(19) United States
(12) Patent Application Publication
(10) Pub. No.: US 2002/0090799 A1
(43) Pub. Date: Jul. 11, 2002

(54) Substrate grinding systems and methods to reduce dot depth variation

(76) Inventors: Krishna Vepa, Livermore, CA (US); Duncan Dobson, Woodside, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 09/851,500

(22) Filed: May 7, 2001

Related U.S. Application Data
(60) Provisional application No. 60/202,363, filed on May 5, 2000.

(51) Int. Cl. H01L 21/46; H01L 21/30; H01L 21/76; B24B 7/30; B24B 7/19; B24B 1/00

(52) U.S. Cl. 438/459; 451/41; 451/63; 451/54; 438/401; 451/65; 451/67

(57) ABSTRACT

The present invention provides exemplary cluster tool systems and methods for processing wafers, such as semiconductor wafers, including exemplary grinding methods and apparatus which provide generally uniform laser marking dot depth. One method of processing wafers prior to device formation includes providing a wafer having first and second surfaces with thickness variations therebetween. The method includes laser marking the first wafer surface, and grinding the first and second wafer surfaces. The grinding removes a portion of the first wafer surface to maintain the laser marking at a uniform depth.

### CROSS-REFERENCES TO RELATED APPLICATIONS

This application claims the benefit of the following U.S. patent applications, the complete disclosures of which are incorporated herein by reference:

U.S. patent application Ser. No. 09/808,790, entitled “Cluster Tool Systems and Methods for Processing Wafers,” (Attorney Docket No. 20468-000110), filed on Mar. 15, 2001;

U.S. Provisional Application No. 60/202,363 (Attorney Docket No. 20468-000900), filed on May 5, 2000; and

U.S. patent application Ser. No. ______, entitled “Cluster Tool Systems and Methods to Eliminate Wafer Waviness During Grinding,” (Attorney Docket No. 20468-001010), filed on Mar. 15, 2001.

### BACKGROUND OF THE INVENTION

The present invention is directed to the processing of wafers, substrates or disks, such as silicon wafers, and more specifically to cluster tool systems and methods for processing wafers prior to device formation.

Wafers or substrates with exemplary characteristics must first be formed prior to the formation of circuit devices. In determining the quality of the semiconductor wafer, the flatness of the wafer is a critical parameter to customers since wafer flatness has a direct impact on the subsequent use and quality of semiconductor chips diced from the wafer. Hence, it is desirable to produce wafers having as near a planar surface as possible. Additionally, circuit devices are being formed having smaller and smaller feature sizes. The desire for such devices dictates that additional precision be incorporated into a number of wafer processes.

In a current practice, cylindrical boules of single-crystal silicon are formed, such as by Czochralski (CZ) growth process. The boules typically range from 100 to 300 millimeters in diameter. These boules are cut with an internal diameter (ID) saw or a wire saw into disc-shaped wafers approximately one millimeter (mm) thick. The wire saw reduces the kerf loss and permits many wafers to be cut simultaneously. However, the use of these saws results in undesirable waviness of the surfaces of the wafer. For example, the topography of the front surface of a wafer may vary by as much as 1-2 microns (μ) as a result of the natural distortions or warpage of the wafer as well as the variations in the thickness of the wafer across its surface. It is not unusual for the amplitude of the waves in each surface of a wafer to exceed fifteen (15) micrometers. The surfaces need to be made more planar (planarized) before they can be polished, coated or subjected to other processes.

FIG. 1 depicts a typical prior art method 10 for processing a silicon wafer prior to device formation. Method 10 includes a slice step 12 as previously described to remove a disc-shaped portion of wafer from the silicon boule. Once the wafer has been sliced, the wafer is cleaned and inspected (Step 14). Thereafter, an edge profile process (Step 16) is performed. Once the edge profile has been performed, the wafer is again cleaned and inspected (Step 18), and is laser marked (Step 20).

Next, a lapping process (Step 22) is performed to control thickness and remove bow and warp of the silicon wafer. The wafer is simultaneously lapped on both sides with an abrasive slurry in a lapping machine. The lapping process may involve one or more lapping steps with increasingly finer polishing grit. The wafer is then cleaned (Step 24) and etched (Step 26) to remove damage caused by the lapping process. The etching process may involve placing the wafer in an acid bath to remove the outer surface layer of the wafer. Typically, the etchant is a material requiring special handling and disposal. Thereafter, an additional cleaning of the wafer (Step 28) is performed. Numerous additional steps follow, including polishing, cleaning and packaging steps.

In another prior art method, a grinding process replaces the lapping procedure of Step 22. A first surface of the wafer is drawn or pushed against a hard flat holder while the second surface of the wafer is ground flat. The forces used to hold the wafer elastically deform the wafer during grinding of the second surface. When the wafer is released, elastic restoring forces in the wafer cause it to resume its original shape, and it can be seen that the waves in the first surface have been transferred to the surface that has been ground. Thus while this technique produces a wafer of more uniform thickness, it does not eliminate the residual saw waves.

A number of deficiencies exist with the prior art method. The prior art method requires a large number of steps to transform a wafer slice into a substrate suitable for creating circuit devices. The large number of process steps involved negatively effects production throughput, requires a large production area, and results in high fabrication costs. Additionally, each of the steps in FIG. 1 are typically performed at individual process stations. The stations are not grouped or clustered together, and manual delivery of the wafers between stations is often used.

In addition to the large number of process steps, at least some of the prior art steps themselves are slow or produce unacceptable results. For example, with reduced shrink widths there is a desire to increase the available wafer area for device formation. If laser marking is performed on the device side of the wafer, then smaller laser marking sizes are necessary. As laser marked characters are more closely spaced, the dot depth becomes important so that the mark can be accurately read. As shown in FIG. 1, laser marking typically is performed prior to lapping or grinding. However, current lapping and grinding techniques remove silicon material from both sides of the wafer simultaneously and in some cases unevenly. Such a process makes it difficult to precisely control dot depth, due in part to the difficulty in controlling the amount of material removal as a function of wafer surface location, and from wafer to wafer.

One attempt to help control the laser marking dot depth uniformity, is to perform a coarse grind or lap to remove much of the wafer thickness variations, laser mark the wafer, and perform additional grind or lap processes. As will be appreciated by those skilled in the art, such a process flow involves additional complexity and time to stop the grinding/lapping, incorporate the laser mark process, and then resume grinding/lapping.

Additional deficiencies in the current art, and improvements in the present invention, are described below and will be recognized by those skilled in the art.

### SUMMARY OF THE INVENTION

The present invention provides exemplary cluster tool systems and methods for processing wafers, such as semiconductor wafers, including exemplary grinding methods and apparatus which provide generally uniform laser marking dot depth. According to the present invention, one method of processing wafers prior to device formation includes providing a wafer having first and second surfaces with thickness variations therebetween. The method includes laser marking the first wafer surface, and grinding the first and second wafer surfaces. The grinding removes a portion of the first wafer surface to maintain the laser marking at a uniform depth.

In one aspect, the laser marking occurs prior to grinding. In another aspect, the first surface grinding removes a desired amount of material ±1 micron from the first surface.

In one embodiment of the present invention, a method of grinding wafers includes providing a cut wafer having initial thickness variations between first and second wafer surfaces, and laser marking a portion of the first surface. The method includes applying a liquid leveling material to the second wafer surface to form a substantially smooth outer surface, positioning the second wafer surface on a grinding tool, and grinding the first surface to form a substantially planar first surface, with the laser marked portion having a plurality of laser marked indentations of substantially uniform depth measured from the first surface. In this manner, generally uniform laser mark dot depth is achieved.

In one aspect, the plurality of indentations have a uniform depth ±1.0 micron. In another aspect, the positioning comprises placing the outer surface on a grinding tool platen. In still another aspect, the method includes grinding the leveling material and second surface to substantially remove the thickness variations while maintaining the substantially uniform indentation depth.

In one aspect of the present invention, the liquid leveling material comprises a liquid polymer that is cured before grinding the first surface. In one aspect, the curing comprises a cure with electromagnetic energy. In another aspect, a polymer film is formed having a thickness between about five (5) microns and about thirty (30) microns. In still another aspect, the polymer and second surface are ground, with the plurality of indentations maintaining their substantially uniform depth.

The present invention further provides exemplary wafer processing apparatus. In one embodiment, the wafer processing apparatus includes a laser marking device for marking the wafer, an applicator for applying a curable liquid to a wafer surface, a curer for curing the curable liquid, a platen for holding the wafer, and a grinder for grinding the wafer surface.

In one aspect, the processing apparatus includes a rotation device coupled to the platen for rotating the wafer. In another aspect, the applicator includes a spin on applicator and the curable liquid comprises a liquid polymer. In some aspects, the curer includes an electromagnetic energy source, which in one embodiment is an ultraviolet light source.

Other objects, features and advantages of the present invention will become more fully apparent from the following detailed description, the appended claims and the accompanying drawings.

### BRIEF DESCRIPTION OF THE DRAWINGS

FIG. 1 depicts a prior art method for processing a silicon wafer;

FIG. 2 is a simplified flow diagram of a wafer processing method according to the present invention;

FIGS. 3A-C depict grind damage cluster tools according to the present invention;

FIGS. 4 and 5 depict simplified flow diagrams of methods of the present invention;

FIGS. 6 and 7A are simplified schematics of wafer preparation and grinding apparatus according to embodiments of the present invention; and

FIG. 7B is a simplified flow diagram showing wafer preparation and grinding methods of the present invention.

### DESCRIPTION OF THE SPECIFIC EMBODIMENTS

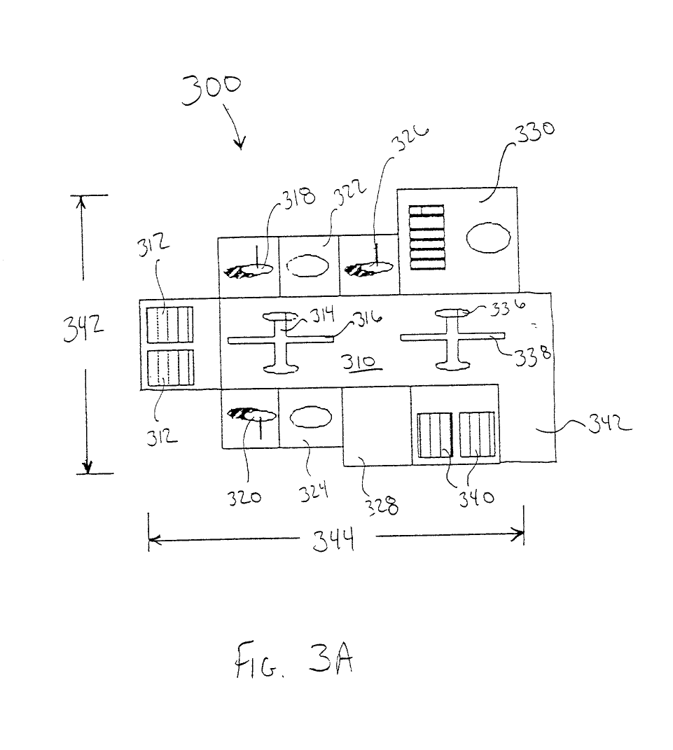

FIG. 2 depicts an exemplary method 200 of the present invention. Method 200 includes a slice process 210, using a wire saw, inner diameter saw or the like, to create a generally disc-shaped wafer or substrate. In one embodiment, the wafer is a silicon wafer. Alternatively, the wafer may comprise polysilicon, germanium, glass, quartz, or other materials. Further, the wafer may have an initial diameter of about 200 mm, about 300 mm, or other sizes, including diameters larger than 300 mm. The wafer is cleaned and inspected (Step 212) and then may, or may not, be laser-marked (Step 214).

Laser marking involves creating an alphanumeric identification mark on the wafer. One or more marks are formed on the wafer used as the substrate of a semiconductor device. One such means of forming the marks includes laser radiation, or laser marking. In laser marking, a portion of the wafer surface is partially melted where a mark is to be made. In one embodiment, the marking is performed by laser beam radiation, such as from an Nd-YAG laser, so that an uneven surface is formed which can be identified by the naked eye or optical device.

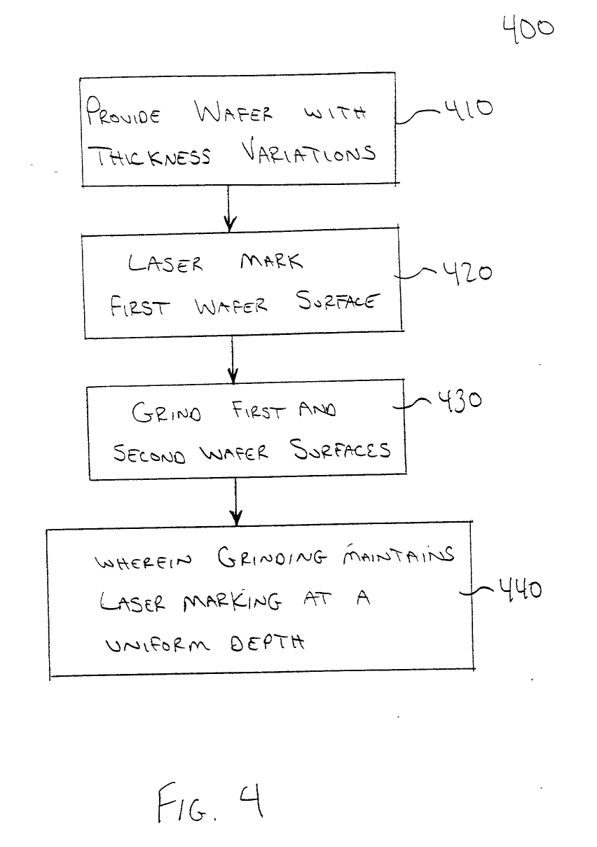

The ID mark may identify the wafer manufacturer, flatness, conductivity type, wafer number and the like. Further details on laser marking character generation, information and interpretation may be found in SEMI Std. M 1.8. The laser marking preferably is performed to a sufficient depth so that the ID mark remains even after portions of the wafer have been removed by subsequent process steps such as grinding, etching, polishing, and the like. Additional details on laser marking according to the present invention are discussed below in conjunction with, for example, FIGS. 4-6.

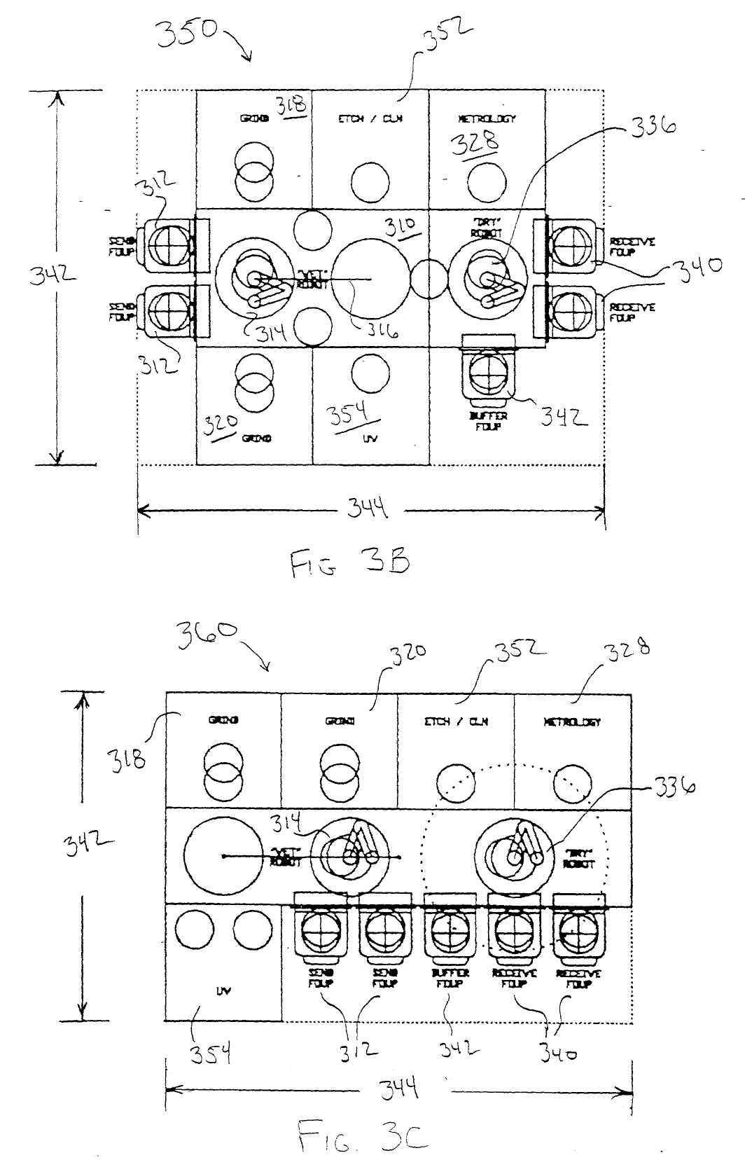

Thereafter, the wafer is processed through a first module (Step 216), with details of embodiments of the first module described below in conjunction with FIGS. 3A-3C. First module processing (Step 216) includes a grinding process, an etching process, a cleaning process and metrology testing of the wafer. In this module, the use of a grinding process in lieu of lapping helps to remove wafer bow and warpage. The grinding process of the present invention also is beneficial in removing wafer surface waves caused by the wafer slicing in Step 210. Benefits of grinding in lieu of lapping include reduced kerf loss, better thickness tolerance, improved wafer shape for polishing and better laser mark dot depth tolerance, and reduced damage, among others. In one embodiment, laser marking is incorporated into the first module processing.

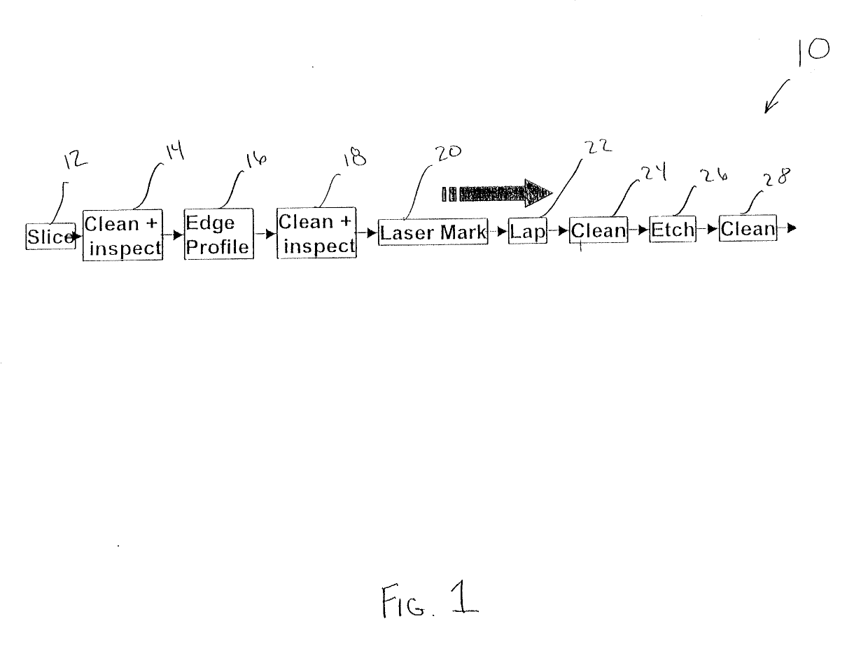

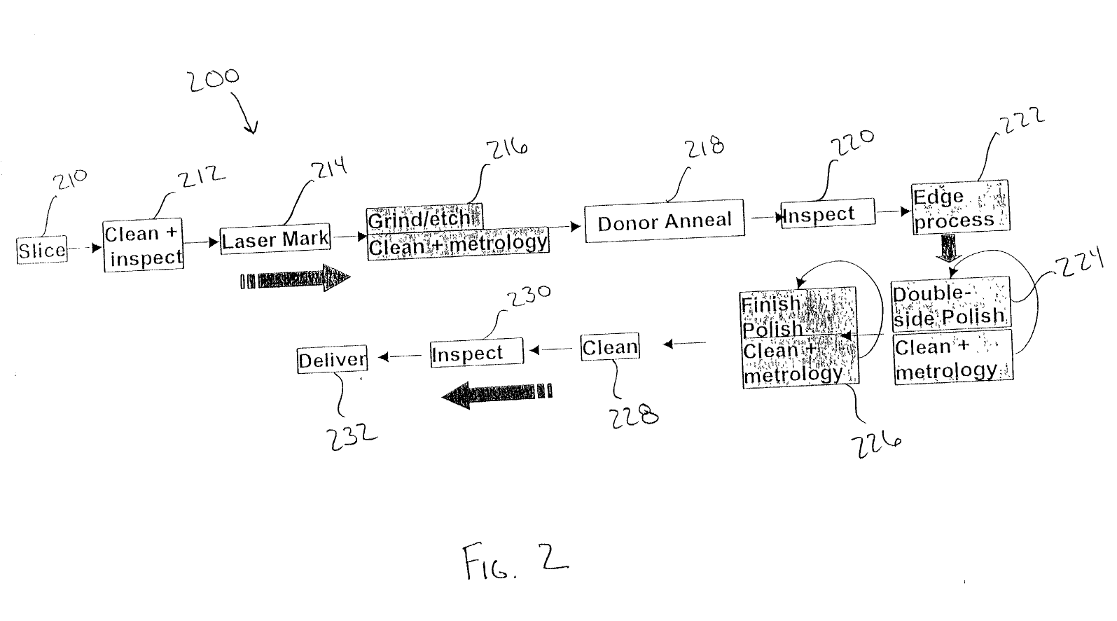

The etching process within the first module is a more benign process than the prior art etch step described in conjunction with FIG. 1. For example, typical prior art etching (Step 26 in FIG. 1) may involve the bulk removal of forty (40) or more microns of wafer thickness. In contrast, the etch process of the present invention preferably removes ten (10) microns or less from the wafer thickness. In one embodiment, the first module etch process removes between about two (2) microns to about five (5) microns of wafer material per side, or a total of about four (4) to about ten (10) microns. In another embodiment, the first module etch process removes between about three (3) microns and about four (4) microns of wafer material per side for a total of about six (6) to about (8) microns.

After first module processing, the wafer is subjected to a donor anneal (Step 218) and thereafter inspected (Step 220). The donor anneal removes unstable oxygen impurities within the wafer. As a result, the original wafer resistivity may be fixed. In an alternative embodiment, donor anneal is not performed.

The wafer then is processed through a second module (Step 222) in which an edge process is performed. The edge process includes both an edge profile and an edge polish procedure. Edge profiling may include removing chips from the wafer edge, controlling the diameter of the wafer and/or the creation of a beveled edge. Edge profiling also may involve notching the wafer to create primary and secondary flat edges. The flats facilitate wafer alignment in subsequent processing steps and/or provide desired wafer information (e.g., conductivity type). In one embodiment, one or both flats are formed near the ID mark previously created in the wafer surface. One advantage of the present invention involves performing the edge profiling after wafer grinding. In this manner, chips or other defects to the wafer edge, which may arise during grinding or lapping, are more likely to be removed. Prior art edge profiling occurs before lapping, and edge polishing subsequent to the lapping step may not sufficiently remove edge defects.

The wafer is then processed through a third module (Step 224). A third module process includes a double side polish, a cleaning process and wafer metrology. Wafer polishing is designed to remove stress within the wafer and smooth any remaining roughness. The polishing also helps eliminate haze and light point defects (LPD) within the wafer, and produces a flatter, smoother finish wafer. As shown by the arrow in FIG. 2, wafer metrology may be used to adjust the double side polishing process within the third module. In other words, wafer metrology may be feed back to the double side polisher and used to adjust the DSP device in the event the processed wafer needs to have different or improved characteristics, such as flatness, or to further polish out scratches.

Thereafter, the wafer is subjected to a finish polish, a cleaning process and metrology testing, all within a fourth process module (226). The wafer is cleaned (Step 228), inspected (Step 230) and delivered (Step 232).

The reduced number of clean and inspection steps, particularly near the end of the process flow, are due in part to the exemplary metrology processing of the wafer during prior process steps. Wafer metrology testing may test a number of wafer characteristics, including wafer flatness, haze, LPD, scratches and the like. Wafer flatness may be determined by a number of measuring methods known to those skilled in the art. For example, “taper” is a measurement of the lack of parallelism between the unpolished back surface and a selected focal plane of the wafer. Site Total Indicated Reading (STIR) is the difference between the highest point above the selected focal plane and the lowest point below the focal plane for a selected portion (e.g., 1 square cm) of the wafer, and is always a positive number. Site Focal Plane Deviation (SFPD) is the highest point above, or the lowest point below, the chosen focal plane for a selected portion (e.g., 1 square cm) of the wafer and may be a positive or negative number. Total thickness variation (TTV) is the difference between the highest and lowest elevation of the polished front surface of the wafer.

Further, metrology information, in one embodiment, is fed back and used to modify process parameters. For example, in one embodiment metrology testing in the first module occurs after wafer grinding and may be used to modify the grinding process for subsequent wafers. In one embodiment, wafers are processed through the first module in series. More specifically, each station within the first module processes a single wafer at a time. In this manner, metrology information may be fed back to improve the grinding or other process after only about one (1) to five (5) wafers have been processed. As a result, a potential problem can be corrected before a larger number of wafers have been processed through the problem area, thus lowering costs.

Further, the present invention produces standard process times for each wafer. More specifically, each wafer is subjected to approximately the same duration of grinding, cleaning, etching, etc. The delay between each process also is the same or nearly the same for each wafer. As a result, it is easy to troubleshoot within the present invention methods and systems.

In contrast, prior art methods typically uses a batch process mode for a number of process steps. For example, a batch containing a large number of wafers (say, twenty (20)) may be lapped one to a few at a time (say, one (1) to four (4) at a time). After all twenty have been lapped, the batch of twenty wafers then are cleaned together as a group (Step 24), and etched together as a group (Step 26). As a result, the wafers that were lapped first sit around for a longer period of time prior to cleaning than do the wafers lapped last. This varying delay effects wafer quality, due in part to the formation of a greater amount of haze, light point defects, and other time-dependent wafer defects. One negative outcome of irregular process times is the resultant difficulty in locating potential problems within the process system.

As with the first module, metrology information may be fed back within the second, third and fourth modules. For example, metrology information may be fed back to the double side polisher or finish polisher to adjust those processes to produce improved results. Additionally, in one embodiment, metrology information is fed back within the third and/or fourth module in real time. As a result, process steps such as the double side polishing can be modified during processing of the same wafer on which metrology testing has occurred.

With reference to FIGS. 3A-3C, additional details on first process modules according to the present invention will be provided. It will be appreciated by those skilled in the art that the process modules described in FIGS. 3A-3C are embodiments of the present invention, from which a number of variations exist within the scope of the present invention. Further, additional process steps may be removed or added, and process steps may be rearranged within the scope of the present invention. Details on additional process modules may be found in U.S. application Ser. No. 09/808,790, the complete disclosure of which has been previously incorporated herein by reference.

FIG. 3A depicts a grind damage cluster module described as first module 216 in conjunction with FIG. 2. First module 300 defines a clean room environment 310 in which a series of process steps are carried out. Wafers that have been processed through Step 214 (FIG. 2) are received in first module 300 via a portal, such as a front opening unified pod (FOUP) 312. First module 300 is shown with two FOUPs 312, although a larger or smaller number of FOUPs/portals may be used. FOUPs 312 are adapted to hold a number of wafers so that the frequency of ingress into the clean room environment 310 may be minimized. A transfer device 314, schematically depicted as a robot, operates to remove a wafer from FOUPs 312 and place the wafer on a grinder 318. If needed, transfer device 314 travels down a track 316 to properly align itself, and hence the wafer, in front of grinder 318. Grinder 318 operates to grind a first side of the wafer.

The wafer may be held down on grinder 318 by way of a vacuum chuck, and other methods. Once grinder 318 has ground the first side of the wafer, the wafer is cleaned in cleaner 322 and the transfer device 314 transfers the wafer back to grinder 318 for grinding the converse side of the wafer. In one embodiment, wafer grinding of both wafer sides removes about forty (40) microns to about seventy (70) microns of wafer thickness. After the second wafer side is ground, the wafer is again cleaned in cleaner 322. In one embodiment, cleaning steps occur on grinder 318 subsequent to grinding thereon. In one embodiment, cleaning and drying are accomplished by spraying a cleaning solution on the wafer held by or near the edges and spun.

In another embodiment, at least one side of the wafer is subjected to two sequential grinding steps on grinder 318. The two grinding processes preferably include a coarse grind followed by a fine grind. Grinder 318 may include, for example, two different grinding platens or pads with different grit patterns or surface roughness. In one embodiment, the wafer is cleaned on grinder 318 between the two grinding steps to the same wafer side. Alternatively, cleaning may occur after both grinding steps to the same wafer side.

In some embodiments, transfer device 314 transfers the wafer from cleaner 322 to a backside polisher 326. For example, this process flow may occur for 200 mm wafers. In this embodiment, the back side is polished and not ground, or both ground and polished.

As shown in FIG. 3A, a second grinder 320 and a second cleaner 324 are provided within module 300. In this manner, two wafers may be simultaneously processed therethrough. Since both grinders 318, 320 have a corresponding cleaner 322, 324, wafer processing times are consistent even if two wafers are being ground simultaneously on grinders 318, 320. In one embodiment, grinders 318 and 320 are used to grind opposite sides of the same wafer. In this case, one side of the wafer is ground on grinder 318 and the other side of the same wafer is ground on grinder 320. As with grinder 318, wafers may be ground on grinder 320 and then cleaned on grinder 320 before removal, or cleaned in cleaner 324.

Once the wafers have been ground, a second transfer device 336, again a robot in one embodiment, operates to transfer the wafer to an etcher 330. Etcher 330 operates to remove material from the wafer, preferably a portion on both primary sides of the wafer. The etching process is designed to remove stresses within the silicon crystal caused by the grinding process. Such an operation, in one embodiment, removes ten (10) microns or less of total wafer thickness. In this manner, etcher 330 operates to remove less wafer material than in prior art etch processes. Further, the present invention requires less etchant solution, and hence poses fewer environmental problems related to disposal of the acids or other etchants.

Wafer metrology is then tested at a metrology station 328. In one embodiment wafer metrology is tested subsequent to grinding on grinder 318, and prior to the etching within etcher 330. Alternatively, wafer metrology is tested subsequent to etching in etcher 330. In still another embodiment, wafer metrology is tested both prior to and subsequent to the etching process. Evaluation of wafer metrology involves the testing of wafer flatness and other wafer characteristics to ensure the wafer conforms to the desired specifications. If the wafer does not meet specifications, the wafer is placed in a recycle area 342, which in one embodiment comprises a FOUP 342 (not shown in FIG. 3A). Wafers with acceptable specifications are placed in an out portal or FOUP 340 for removal from first module 300.

As shown and described in conjunction with FIG. 3A, first module 300 provides an enclosed clean room environment in which a series of process steps are performed. Wafers are processed in series through first module 300. Hence, each wafer has generally uniform or uniform process time through the module as well as generally uniform or uniform delay times between process steps. Further, by immediately cleaning and etching the wafer after grinding, the formation of haze and light point defects (LPD) within the wafer are reduced. Such a module configuration is an improvement over the prior art in which wafers are typically processed during the lapping step in batch mode. As a result, some wafers will wait longer before the cleaning or etching steps than others within the same batch. As a result, haze and other wafer defects vary from wafer to wafer, even between wafers within the same batch. Such a shortcoming of the prior art can make it difficult if not impossible to isolate problems within the wafer process flow in the event defective wafers are discovered.

An additional benefit of first module 300 is its compact size. In one embodiment, module 300 has a width 342 that is about 9 feet 3 inches and a length 344 that is about 12 feet 6 inches. In another embodiment, first module 300 has a footprint between about ninety (90) square feet (sqft) and about one hundred and fifty (150) square feet. It will be appreciated by those skilled in the art that the width and length, and hence the footprint of first module 300, may vary within the scope of the present invention. For example, additional grinders 318, 320 may be added within first module 300 to increase the footprint of module 300. In one embodiment, first module 300 is adapted to process about thirty (30) wafers per hour. In another embodiment, first module 300 is adapted to process between about twenty-nine (29) and about thirty-three (33) 300 mm wafers per hour.

FIG. 3B depicts an alternative embodiment of a grind damage cluster module according to the present invention. Again, the grind damage cluster module 350 may correspond to first module 216 described in conjunction with FIG. 2. Module 350 includes many of the same components as the embodiment depicted in FIG. 3A, and like reference numerals are used to identify like components. Module 350 receives wafers or substrates to be processed at portal 312, identified as a send FOUP 312 in FIG. 3B. Wafers are transferred by transfer device 314, shown as wet robot 314, to a preprocessing station 354. In one embodiment, transfer device 314 travels on a track, groove, raised member or other mechanism which allows transfer device 314 to reach several process stations within module 350.

At preprocessing station 354, a coating is applied to one side of the wafer. In one embodiment, a polymer coating is spun on the wafer to provide exemplary coverage. This coating then is cured using ultraviolet (UV) light to provide a low shrink, rapid cured coating on one side of the wafer. In addition to UV curing, curing of the coating may be accomplished by heating and the like. In a particular embodiment, the coating is applied to a thickness between about five (5) microns and about thirty (30) microns.

Once cured, the coating provides a completely or substantially tack free, stress free surface on one side of the wafer. In one embodiment of the present invention, transfer device 314 transfers the wafer to grinder 318, placing the polymer-coated side down on the grinder 318 platen. In one embodiment, the platen is a porous ceramic chuck which uses a vacuum to hold the wafer in place during grinding. The waves created during wafer slicing are absorbed by the coating and not reflected to the front side of the wafer when held down during the grinding process. After the first wafer side is ground on grinder 318, the wafer is flipped over and the second side is ground. As described in conjunction with FIG. 3A, an in situ clean of the wafer may occur before turning the wafer, or the wafer may be cleaned subsequent to grinding of both sides. Again, the second side grinding may occur on grinder 318 or grinder 320. Grinding of the second side removes the cured polymer, and a portion of the second wafer surface resulting in a generally smooth wafer on both sides, with little to no residual surface waves. Additional details on exemplary grinding apparatus and methods of the present invention are discussed in conjunction with FIGS. 4-7B.

After grinding on grinder 318 and/or 320, the wafer is transferred to a combined etch/clean station 352 for wafer etch. Again, wafer etching in station 352 removes a smaller amount of wafer material, and hence requires a smaller amount of etchant solutions, than is typically required by prior art processes.

Processing continues through module 350 ostensibly as described in FIG. 3A. The wafer metrology is tested at metrology station 328. Wafers having desired characteristics are transferred by transfer device 336, shown as a dry robot, to out portals 340, identified as receive FOUPS 340 in FIG. 3B. Wafers having some shortcoming or undesirable parameter are placed in a recycle area 342, shown as a buffer FOUP 342, for appropriate disposal.

In one embodiment, module 350 has a width 342 at its widest point of about one hundred and fourteen (114) inches, and a length at its longest point of about one hundred and forty-five inches (145), with a total footprint of about one hundred and fourteen square feet (114 sqft). As will be appreciated by those skilled in the art, the dimensions and footprint of module 350 may vary within the scope of the present invention.

Still another embodiment of a grind damage cluster module according to the present invention is shown in FIG. 3C. FIG. 3C depicts a first module 360 having similar stations and components as module 350 described in FIG. 3B. However, module 350 is a flow through module, with wafers being received at one end or side of module 350 and exiting an opposite end or side of module 350. Module 360 has FOUPS 312, 342 and 340 grouped together. Such a configuration provides a single entry point into module 360, and hence into clean room environment 310. Transfer devices 314 and 336 again facilitate the movement of wafers from station to station within module 360. As shown in FIGS. 3B and 3C, transfer device 314 travels on mechanism 316, as discussed in conjunction with FIG. 3B. Transfer device 336 operates from a generally fixed position with arms or platens extending therefrom to translate the wafer to the desired processing station. Module 360 further includes station 354 for application of a wafer coating, such as the UV cured polymer coating described above.

The above-described processes and process modules may be used in conjunction with exemplary laser marking processes and apparatus of the present invention. As previously described, in one embodiment, the present invention involves single side grinding of wafers or substrates. The grinding processes of the present invention help precisely control the removal rate of each surface of the wafer. In one embodiment, a desired or target amount of material removed is about 25-40 microns per wafer surface, and in another embodiment is about 35 microns per wafer surface. After grinding a first wafer surface, the wafer is then flipped over and the second wafer surface is ground to produce the desired final wafer thickness. In one embodiment, the grinding tolerance for each face is ±1.0 micron. As a result, in one embodiment the dot depth variation ranges from ±1.0 micron after the substrate surface is ground.

As shown in FIG. 4, one method 400 of the present invention includes providing a wafer having thickness variations (410). The first wafer surface is laser marked (420) and the first and second wafer surfaces are ground (430). The grinding process maintains the laser marking at a generally uniform depth (440). In one embodiment, the generally uniform dot depth is maintained due in part to the improved grinding tolerances of the present invention.

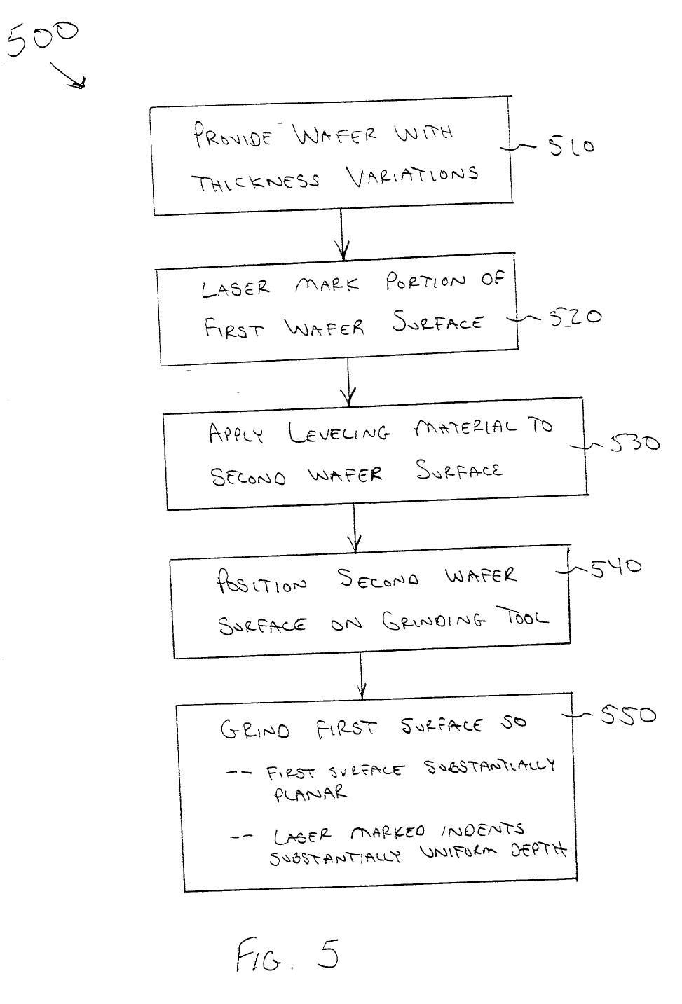

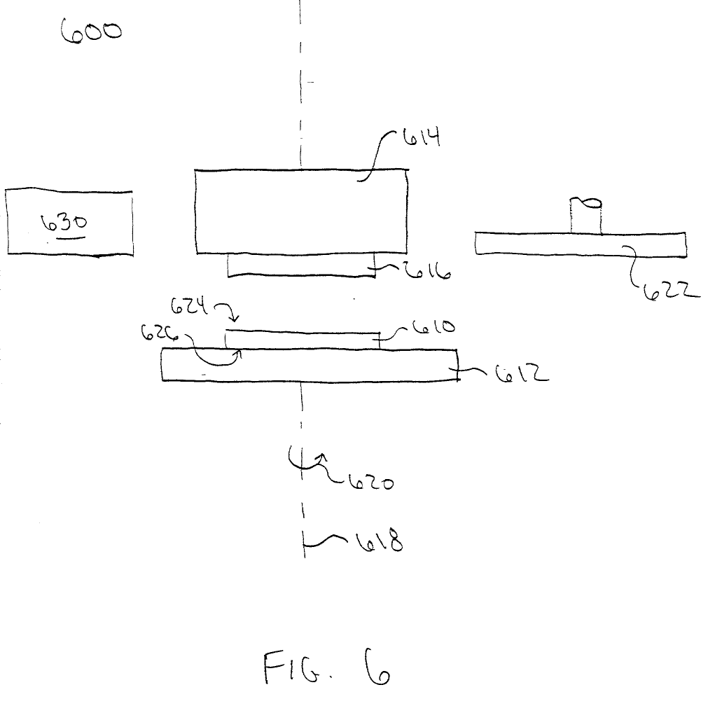

In another embodiment shown in FIG. 5, a method 500 according to the present invention is described. Method 500 includes providing a wafer having thickness variations (510), and laser marking a portion of a first wafer surface (520). Method 500 includes applying a leveling material to a second wafer surface (530), and positioning the second wafer surface on a grinding tool (540). Method 500 further includes grinding the first surface so that the first surface is substantially planar and the laser marked indentations have substantially uniform depth (530). In this manner, and partly as a result of exemplary grinding processes of the present invention, laser marking has a substantially uniform dot depth. With such uniform dot depth, the laser marked bar code or character may be optically read with greater consistency and precision. This is particularly the case for laser marks having a more tightly packed series of dots providing the laser mark information. Since light scatter is a function of the slope and depth of the dots or indentations, it is beneficial to have the physical markings on the wafer with precise dimensions. Apparatus and methods of the present invention provide such desired precision. An exemplary apparatus 600 according the present invention is shown in FIG. 6.

Apparatus 600 for grinding a wafer according to the present invention will be described. In one embodiment, apparatus 600 may be incorporated into the process modules described in conjunction with FIGS. 3A-3C. Alternatively, the laser marking devices and processes may be performed outside the first modules. In one embodiment, a wafer or substrate 610 having thickness variations between two sides is provided. Substrate 610 is laser marked as described herein using a laser mark device 630. In one embodiment, laser mark device 630 is an Nd-YAG laser, other irradiation devices capable of locally melting wafer material, and the like. Apparatus 600 has a platen 612, on which is placed substrate 610 to be planarized by grinding. An applicator or dispenser 614 applies a curable liquid leveling material to a first surface 624 of substrate 610. In this case, first surface 624 is an upper surface, although different wafer orientations are within the scope of the present invention. The curable liquid, in one embodiment, comprises a liquid polymer, a liquid resin, an acrylic, an epoxy, and the like. In a particular embodiment, the curable material is an acrylic or epoxy obtained from Lens Technology LLC in La Mirada, Calif.

In one embodiment, the curable liquid is applied using a spin-on process. For example, platen 612, and hence substrate 610, may be rotated about an axis 618 as indicated by arrow 620. Preferably, rotation of platen 612 is in a continuous 360° fashion, and may be clockwise or counterclockwise. By rotating platen 612 simultaneous with the spraying or application of a curable liquid by applicator 614, the liquid spreads out over surface 624. By controlling the curable liquid viscosity, dispense time, dispense rate, and/or the wafer 610 angular velocity, the film thickness formed by the curable liquid may be controlled.

Preferably, apparatus 600 includes a curer 616. Curer 616 is adapted to cure the spun-on curable liquid in order to harden the liquid onto surface 624. In alternative embodiments, curer 616 provides an electromagnetic energy, an ultraviolet light, and the like. Additionally, curer 616 may be a heat source, such as a heat lamp, for use with curable liquids that are cured using elevated temperatures. While shown coupled to applicator 614, curer 616 may be a separate device uncoupled from applicator 614. As previously described in conjunction with FIG. 3B, the curable liquid, when hardened, forms a substantially planar or smooth upper surface notwithstanding any surface irregularities, waves or undulations otherwise present in surface 624. In one embodiment, surface 624, having a coating or film of hardened curable liquid or polymer, is placed on platen 612. In one embodiment, apparatus 600 includes a grinder 622 which is positioned over substrate 610 to facilitate grinding processes thereof.

Grinding processes of the present invention provide for increased grinding tolerances than previously obtained. For example, grinding removes a desired amount of wafer material from the wafer surfaces. In one embodiment, the grinding of the laser-marked wafer surface reduces the wafer thickness by a desired amount, ±1.0 microns. In another embodiment, the grinding tolerance is within ±2.0 microns. As a result, the laser marking dot depth will have similar or the same depth variations on the substrate, or between substrates processed through the same modules. As a result of the smaller dot depth variations, the laser mark is more easily and accurately read or optically scanned.

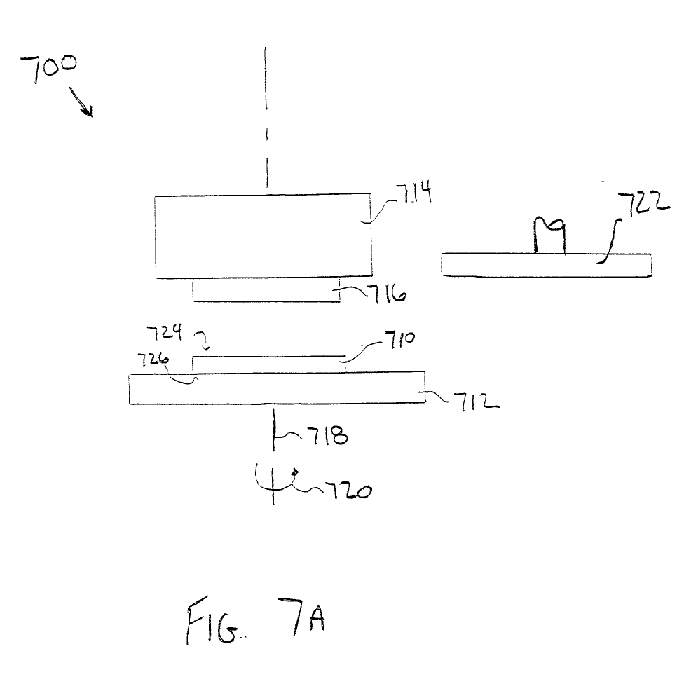

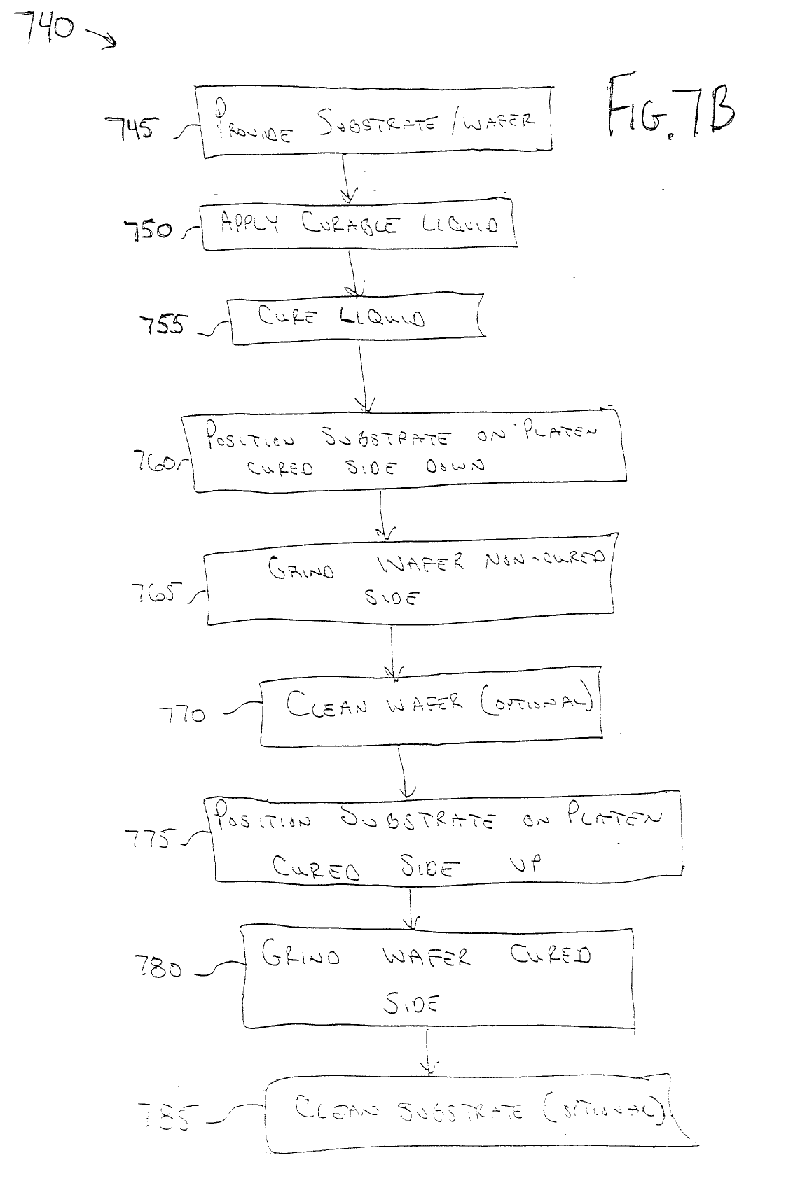

Turning now to FIGS. 7A and 7B, additional exemplary methods and apparatus for grinding a wafer will be described. In one embodiment, a wafer or substrate 710 having thickness variations between two sides is provided. In one embodiment, wafer 710 has been laser marked prior to introduction into an apparatus 700. Hence, apparatus 700 does not include a laser mark device. Again, apparatus 700 may be incorporated into first process modules of FIGS. 3A-3C. Apparatus 700 has a platen 712, on which is placed substrate 710 to be planarized by grinding. An applicator or dispenser 714 applies a curable liquid to a first surface 724 of substrate 710. In this case, first surface 724 is an upper surface, although different wafer orientations are within the scope of the present invention. The curable liquid, in one embodiment, comprises a liquid polymer, a liquid resin, an acrylic, an epoxy, and the like. In a particular embodiment, the curable material is an acrylic or epoxy obtained from Lens Technology LLC in La Mirada, Calif.

In one embodiment, the curable liquid is applied using a spin-on process. For example, platen 712, and hence substrate 710, may be rotated about an axis 718 as indicated by arrow 720. Preferably, rotation of platen 712 is in a continuous 360° fashion, and may be clockwise or counterclockwise. By rotating platen 712 simultaneous with the spraying or application of a curable liquid by applicator 714, the liquid spreads out over surface 724. By controlling the curable liquid viscosity, dispense time, dispense rate, and/or the wafer 710 angular velocity, the film thickness formed by the curable liquid may be controlled.

Preferably, apparatus 700 includes a curer 716. Curer 716 is adapted to cure the spun-on curable liquid in order to harden the liquid onto surface 724. In alternative embodiments, curer 716 provides an electromagnetic energy, an ultraviolet light, and the like. Additionally, curer 716 may be a heat source, such as a heat lamp, for use with curable liquids that are cured using elevated temperatures. While shown coupled to applicator 714, curer 716 may be a separate device uncoupled from applicator 714. As previously described in conjunction with FIG. 3B, the curable liquid, when hardened, forms a substantially planar or smooth upper surface notwithstanding any surface irregularities, waves or undulations otherwise present in surface 724. In one embodiment, surface 724, having a coating or film of hardened curable liquid or polymer, is placed on platen 712. In one embodiment, apparatus 700 includes a grinder 722 which is positioned over substrate 710 to facilitate grinding processes thereof.

Turning now to FIG. 7B, an exemplary method 740 according to the present invention will be described. The method includes providing a substrate or wafer having surface irregularities or thickness variations to be removed (Step 745). Such surface irregularities may comprise generally horizontal lines or grooves formed in surface 724 during wire saw operation to cut substrate 710 from the boule. A curable liquid, such as a curable polymer, resin and the like is applied (750) to surface 724. Thereafter the liquid is cured to a hardened state (755), and the substrate is positioned (760) on the grinding apparatus platen with the surface 724 side down. Thereafter, the non-cured side of the wafer, surface 726, is ground (765) to be planar or substantially planar. An optional clean procedure (770) may be formed on wafer 710, such as on surface 726. Once wafer surface 726 has been ground, the substrate is repositioned (775) to place surface 726 on platen 712. Thereafter, grinder 722 grinds both the cured coating and a portion of wafer surface 724 (Step 780). Thereafter, an optional wafer clean may be performed (785).

Another particular embodiment of the present invention will now be described. Substrate 710 having surface irregularities and/or thickness variations is coupled to platen 712 and cleaned. In one embodiment, substrate 710 cleaning comprises applying RCA1, SC1, some combination of ammonia, peroxide and water, or the like, to substrate 710 for about ten (10) to about fifteen (15) seconds while platen 712 and substrate 710 are spun. Substrate 710 is dried through the application of isopropyl alcohol (IPA) or the like, again while spinning, with the spinning accelerating up to about 1,200 to about 1,800 revolutions per minute (RPM).

Applicator 714 then dispenses the curable material on wafer 710 for a duration sufficient to wet all or substantially all of first surface 724. Curable material may flow over the peripheral edges of substrate 710. The platen speed during dispensing ranges from about sixty (60) RPM to about one hundred and eighty (180) RPM in one embodiment. In an alternative embodiment, applicator 714 is rotated or spun during dispensing. In one embodiment, the volume of curable material used ranges from about 10 milliliters (ml) to about 25 ml, although the volume may differ from this amount depending in part on the substrate 710 size and surface 724 topography. In an embodiment, apparatus 700 further includes an ultrasound device (not shown) for producing ultrasound energy to facilitate the distribution of curable material over surface 724. In one embodiment, substrate 710 then is rotated at about 800 RPM to about 2,500 RPM for about five (5) to about ten (10) seconds, or longer, after which the substrate is allowed to settle at a lower RPM. Rotating substrate 710 after dispensing the curable material helps the material spread over surface 724.

Curer 716 then operates to cure the curable material coating on surface 724. In one embodiment, curer 716 is a UV lamp have a spectrum range of about 250 nm to about 800 nm. In one embodiment, curer 716 is positioned about two (2) to about six (6) inches from first surface 724, and in a particular embodiment is positioned about three (3) inches from surface 724, while curer 716 applies electromagnetic energy to surface 724. In one embodiment, substrate 710 is spun during the application of electromagnetic energy. As a result, the coating of surface 724 fills or substantially fills the undulations in surface 724. In some embodiments, the coating has a thickness ranging from about five (5) microns to about forty (40) microns, from about fifteen (15) microns to about thirty (30) microns, and from about fifteen (15) to about forty (40) microns. The coating is a hard, substantially scratch resistant material that is relatively uncompressed. As a result, no thermal gradients are formed, and little to no localized stresses are formed due to thermal mismatches that may otherwise occur when waxes or other adhesives are used. Grinding operations as described herein ensue.

Hence, as provided in methods of the present invention, the cured coating provides a substantially planer and hard surface on which to mount the substrate. By doing so, wafer surface 726 may be ground flat with little to no surface reflection resulting from irregularities in wafer surface 724. The cured coating and wafer surface 724 then are subjected to grinding processes. As a result, a substantially planar wafer having generally uniform thickness between two opposite sides is produced. Local uniformity also is improved.

A number of benefits result from the above-described apparatus and methods of the present invention. For example, each wafer uses a fresh film of polymer, resin, or the like, thus avoiding any issues related to wear and tear of the pads, platens and the like. Also, the coating may be ground off the wafer, thereby avoiding environmental issues otherwise associated with cleansing solutions used to clean grease, wax, or the like that may otherwise be used to hold the wafer during grinding. Further, the cured coating protects the wafer backside during grinding procedures and from chemical attack that may otherwise occur. Still further, the intimate contact of the wafer surface with the cured coating, due to interfacial Van der waals forces, insures a more homogeneous force distribution during the grinding process. The cured coating provides a stress free or substantially stress free wafer-coating interface, as well as coating removal. As a result, the wafer suffers less surface distortion and produces better wafer-to-wafer consistency. Further, laser marked dot depth is uniform or substantially uniform due to the exemplary grinding processes described herein.

The invention has now been described in detail for purposes of clarity and understanding. However, it will be appreciated that certain changes and modifications may be practiced within the scope of the appended claims. For example, the modules may have different layouts, dimensions and footprints than as described above. Additionally, transfer devices that have been described as traveling or fixed, may also be fixed or traveling, respectively. Further, laser marking described above may occur before grinding, between grinding steps, or after grinding.

What is claimed is:

1. A method of processing a wafer prior to device formation thereon, said method comprising:
providing a wafer having first and second surfaces with thickness variations therebetween;
laser marking said first wafer surface; and
grinding said first and second wafer surfaces;
wherein said grinding removes a portion of said first wafer surface to maintain said laser marking at a uniform depth.

2. The method as in claim 1 wherein said laser marking occurs prior to said grinding.

3. The method as in claim 1 wherein said grinding said first surface removes a desired amount of material ±1 micron from said first surface.

4. A method of grinding wafers, said method comprising:
providing a cut wafer having initial thickness variations between first and second wafer surfaces;
laser marking a portion of said first surface;
applying a liquid leveling material to said second wafer surface to form a substantially smooth outer surface;
positioning said second wafer surface on a grinding tool; and
grinding said first surface to form a substantially planar first surface, said laser marked portion having a plurality of laser marked indentations of substantially uniform depth measured from said first surface.

5. The method of claim 4 wherein said plurality of indentations have a uniform depth ±1.0 micron.

6. The method as in claim 4 wherein said positioning comprises placing said outer surface on a grinding tool platen.

7. The method as in claim 4 further comprising grinding said leveling material and said second surface to substantially remove said thickness variations while maintaining said substantially uniform depth.

8. The method as in claim 4 wherein said applying said liquid leveling material comprises applying a liquid polymer to said second surface, said method further comprising curing said liquid polymer before grinding said first surface.

9. The method as in claim 8 wherein said curing comprises a cure with electromagnetic energy.

10. The method as in claim 8 wherein said applying said polymer forms a polymer film having a thickness between about five (5) microns and about thirty (30) microns.

11. The method as in claim 8 further comprising grinding said polymer and said second surface, said plurality of indentations maintaining said substantially uniform depth.

12. A wafer processing apparatus, comprising:
a laser marking device for marking said wafer;
an applicator for applying a curable liquid to a wafer surface;
a curer for curing said curable liquid;
a platen for holding said wafer; and
a grinder for grinding said wafer surface.

13. The apparatus as in claim 12 further comprising a rotation device coupled to said platen for rotating said wafer.

14. The apparatus as in claim 12 wherein said applicator comprises a spin on applicator and said curable liquid comprises a liquid polymer.

15. The apparatus as in claim 12 wherein said curer comprises an ultraviolet light source.

16. The apparatus as in claim 12 wherein said curer comprises an electromagnetic energy source.
